(19) United States
(12) Patent Application Publication
(10) Pub. No.: US 2002/0081801 A1
(43) Pub. Date: Jun. 27, 2002

(54) Process for producing a microroughness on a surface

(76) Inventors: Matthias Forster, Dresden (DE); Anja Morgenschweis, Dresden (DE); Torsten Martini, Dresden (DE); Jens-Uwe Sachse, Dresden (DE)

Correspondence Address: LERNER AND GREENBERG, P.A., PATENT ATTORNEYS AND ATTORNEYS AT LAW, Post Office Box 2480, Hollywood, FL, 33020-2480, US

(21) Appl. No.: 09/901,526

(22) Filed: Jul. 9, 2001

(30) Foreign Application Priority Data
Jul. 7, 2000 (DE) 100 34 005.9

(51) Int. Cl. H01L 21/20; H01L 21/8242

(52) U.S. Cl. 438/245; 438/388; 438/508; 438/964

(57) ABSTRACT

A microroughness on a surface is produced in a single process step by forming semiconductor grains directly from a process gas. The semiconductor grains are finely distributed on the surface. As a result of forming the microroughness in a single process step, time and costs are saved during fabrication.

### BACKGROUND OF THE INVENTION

Field of the Invention

The present invention relates to a process for producing a microroughness on a surface, and in particular to a process for producing a microroughness in a trench capacitor of a semiconductor memory cell.

In recent years, the cell size of semiconductor memories has been constantly reduced, thereby increasing the packing density.

Capacitances of semiconductor memory cells are a function of a variety of different parameters, one parameter being the capacitor surface area. With an increasing packing density and an associated decreasing pattern size, it is usually necessary to maintain a sufficient capacitor surface area within an increasingly small space, in order to maintain a technologically required minimum storage capacitance.

Such an increase in surface area is obtained, for example, in the case of a so-called deep trench technology, in which the capacitors are formed in deep trenches in the semiconductor substrate, by deeper etching of the trenches and/or by widening them in their lower region. However, even deeper etching of the trenches is very expensive and technically highly complex, and is therefore hardly suitable for mass production. On the other hand, the possibility of widening the trenches in their lower regions is laterally restricted by adjacent trenches, and consequently further packing is not possible to the desired extent.

In the case of the so-called stack technology, a further increase in the surface area is customarily achieved using what is known as the HSG (hemispherical grain) process. This HSG process is a relatively complex process for producing a microroughness on a surface. The process substantially involves three successive steps, firstly a deposition of amorphous silicon, followed by a seeding to form seed cells on the amorphous silicon layer, and finally an anneal, in which Si grains or Si droplets are formed using the seed cells and by transformation or decomposition of the amorphous silicon layer. Although the microroughness produced in this way leads to a significant increase in surface area, the process is expensive and time-consuming.

### SUMMARY OF THE INVENTION

It is accordingly an object of the invention to provide a process for producing a microroughness on a surface which overcomes the above-mentioned disadvantages of the heretofore-known processes of this general type and which can be implemented in a simple, time-saving and inexpensive way.

With the foregoing and other objects in view there is provided, in accordance with the invention, a process for producing a microroughness on a surface, the process includes:

forming, in a single process step, semiconductor grains directly from a process gas such that the semiconductor grains are finely distributed on a surface for producing a microroughness on the surface.

The process is simplified significantly in particular by the finely distributed formation of semiconductor grains from a process gas in a single step. As a result, time and costs are saved.

Si grains are preferably formed on the surface through the use of a silane-containing process gas. However, it is also possible for Ge grains to be formed through the use of a germanium-containing process gas such as GeH₄.

The semiconductor grains are preferably formed in a temperature range from 500 to 600 degrees Celsius, at a pressure of from 13 to 80 Pascal (100 to 600 mTorr) and with deposition times of from 5 to 60 minutes. Under suitable conditions, it is possible to dispense with a growth of the amorphous layer followed by annealing, the semiconductor grains being formed on the surface directly from the gas phase. Particularly in the case of trench capacitors, it is in this way possible to avoid unnecessary narrowing of the trenches caused by the amorphous layer, so that further “shrinks” become possible. Furthermore, the conventional processes for increasing a surface area which have been described above, such as widening of the trenches or further deepening, can allow an additional increase in capacitance when used in combination with the process according to the invention. Since the process parameters do not cause any problems, it is also possible to implement an inexpensive batch process, in which a large number of wafers are processed simultaneously. Furthermore, it is possible to use ordinary LPCVD (low-pressure chemical vapor deposition) installations without problems, so that it is possible, in particular with the relatively short process time, to achieve significant savings during fabrication.

According to another mode of the invention, an oxide, a nitride or a Si-substrate is used as the surface on which the semiconductor grains are formed.

According to yet another mode of the invention, the Si substrate is precleaned.

According to a further mode of the invention, the precleaning step includes a piranha cleaning, an RCA cleaning and/or a HF-dip cleaning. A piranha cleaning solution typically includes hydrogen peroxide and sulfuric acid. An RCA cleaning may for example use a first cleaning solution including an ammonium hydroxide/hydrogen peroxide solution and a second cleaning solution including a hydrochloric acid/hydrogen peroxide solution. A HF-dip cleaning typically involves dipping the wafers in a solution of water and hydrofluoric acid.

According to another mode of the invention, the process gas has an H₂ dilution in a range from 1:20 to 1:0.2.

According to yet another mode of the invention, the process gas has an N₂ dilution in a range from 1:100 to 1:5.

Other features which are considered as characteristic for the invention are set forth in the appended claims.

Although the invention is illustrated and described herein as embodied in a process for producing a microroughness on a surface, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a scanning electron microscope image of a surface with a microroughness and deep trenches in accordance with the present invention;

FIG. 2 is a simplified sectional view of a process furnace for carrying out the process according to the invention;

FIG. 3 is a chart illustrating a grain height and a grain spacing for different deposition times;

FIG. 4 is a chart illustrating the grain height and the grain spacing as a function of a deposition temperature;

FIG. 5 is a chart illustrating the grain height and the grain spacing as a function of a dilution ratio and the deposition time;

FIG. 6 is a chart illustrating the grain height and the grain spacing as a function of the dilution ratio, the deposition time and a type of surface;

FIG. 7 is a chart illustrating the grain height and the grain spacing as a function of a preliminary cleaning; and

FIG. 8 is a graph illustrating an increase in surface area as a function of a relative grain spacing in accordance with an ideal model.

### DESCRIPTION OF THE PREFERRED EMBODIMENTS

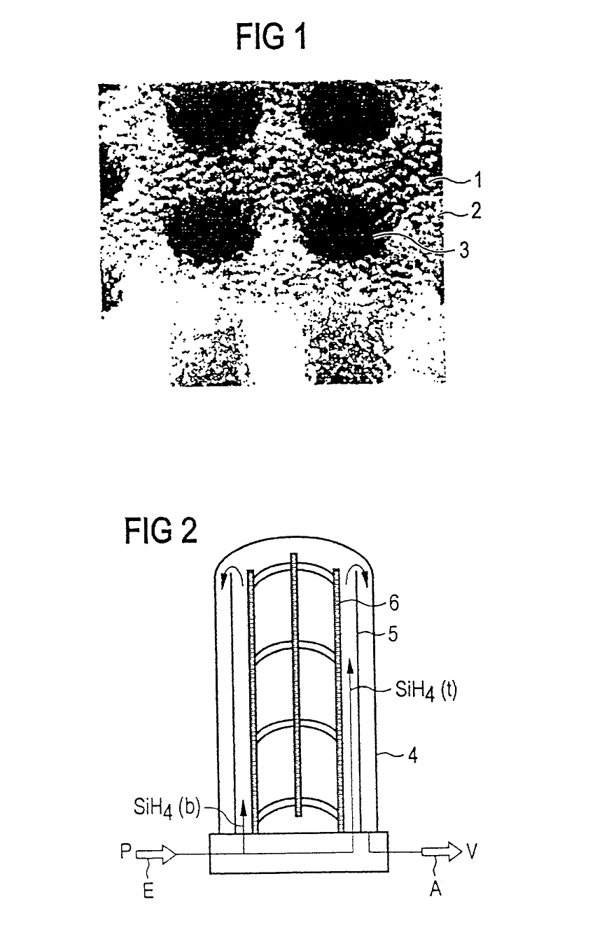

Referring now to the figures of the drawings in detail and first, particularly, to FIG. 1 thereof, there is shown a scanning electron microscope image of a surface 2 with deep trenches 3 as are used, for example, to form trench capacitors in DRAM (dynamic random access memory) semiconductor memory cells. To increase the surface area 2, there are, as shown in FIG. 1, a large number of semiconductor grains 1 on the wafer surface and inside the trenches 3. Therefore, the microroughness on the surface 2 which is brought about by the large number of semiconductor grains 1 immediately increases a capacitance of a trench capacitor formed in the trenches 3. The semiconductor grains 1 are in this case formed in a single process step on the surface 2 and in the trenches 3, resulting in a significant time and cost saving compared to the conventional HSG process described above.

FIG. 2 shows a simplified sectional view of a process furnace as can be used to carry out the process according to the invention. The LPCVD (low-pressure chemical vapor deposition) furnace illustrated in FIG. 2 is, for example, a furnace of the AVP-8000 type, produced by SILICON VALLEY GROUP. As shown in FIG. 2, the structure of this double-walled vertical furnace is as follows: an outer tube 4 closes off a process chamber with respect to the outside. An inner tube 5 has a smaller diameter and lies coaxially inside the outer tube 4. A heating device, which is not shown, is situated outside the outer tube 4. What is known as a boat 6 is used to hold the wafers and is introduced into the inner tube 5, after it has been loaded with the wafers.

Feed lines E for the various process gases P lie in the region of the base. The process gas used may, for example, be silane (SiH₄). Inlet/outlet openings for the process gas are situated in the bottom and top regions inside the inner tube 5, denoted by SiH₄ (b) and SiH₄ (t). The process gas flows inside the inner tube 5, through spaces between the wafers and upward past these wafers, while a small proportion reacts chemically on the hot surfaces of the wafers and the process chamber, resulting in the formation of the semiconductor grains. Between the inner tube 5 and outer tube 4, the process gas flows back downward and is extracted via a connection A to the vacuum pump V. The process gas used is usually silane, which may be diluted by carrier gases or inert gases, such as nitrogen, hydrogen, helium or argon.

The significant advantage of the present invention resides in particular in the use of a conventional vertical furnace of this type and the formation of finely distributed semiconductor grains 1 from the process gas P on the surface 2 in a single step. Unlike the conventional HSG process which has been described above, therefore, no amorphous layer is formed and also no subsequent seeding and anneal is carried out, but rather the semiconductor grains 1 are deposited or formed directly at pressures which are customarily used for LPCVD processes. This process for producing microroughness on a surface which has surprisingly been discovered by the inventors can be carried out in a single process step.

The text which follows describes a large number of tests aimed at increasing the surface area which use silicon grains as the semiconductor grains 1, but it is also possible to form germanium grains in the same way.

To determine a relationship between the grain height and the grain spacing and a deposition time, the latter is varied in a series of tests, the pressure being fixed at 26.6 Pascal (200 mTorr) and the temperature at 560 degrees Celsius. The other process parameters are 200 sccm (standard cubic centimeters per minute) for SiH₄ (b), 100 sccm for SiH₄ (t) and 70 sccm for the dilution gas H₂. In all the tests, the boat is completely loaded with wafers. The process results are determined on test wafers with a 30 nm thick oxide layer. These test wafers are introduced in a central position of the vertical furnace as shown in FIG. 2. At a deposition time of 19 minutes and 10 seconds, a minimum grain height of 55 nm and a maximum grain height of 57 nm is measured. Furthermore, with this deposition time a continuous layer of approx. 30 nm which surrounds the grains is determined. Consequently, this deposition time and the associated process parameters do not produce any significant increase in the surface area.

In a further test, the deposition time is limited (with otherwise identical process parameters) to 12 minutes and 40 seconds, with a minimum grain height of 48 nm and a maximum grain height of 52 nm being determined. In this case, the start of the layer formation between the grains with a thickness of approx. 5 to 10 nm is recorded.

If the deposition time is reduced further (with otherwise identical process parameters) to 9 minutes and 30 seconds, the result is a minimum grain height of 35 nm and a maximum grain height of 59 nm, with the result that individual semiconductor grains are formed close together and there is a significant increase in the surface area.

If the deposition time is reduced further, to 6 minutes, with otherwise identical process parameters, the result is a minimum grain height of 21 nm and a maximum grain height of 37 nm for a wafer in the central region of the vertical furnace.

Consequently, it is possible to form individual grains, resulting in a significant increase in the surface area. In this case, additional test wafers were loaded in the top and bottom regions of the furnace during the same “furnace run”. In all the tests, the entire boat was always loaded with 120 or 175 wafers, known as dummy wafers, but only the test wafers were assessed.

The test wafer in the upper region of the furnace even reveals slightly larger grains, with a minimum height of 27 nm and a maximum height of 42 nm. In the lower region of the furnace, a wafer, with otherwise identical process parameters, has minimum grain heights of 16 nm and maximum grain heights of 28 nm, a continuous layer with a thickness of approx. 12 nm enclosing the grains and the center of the wafer becoming rougher than the edge of the wafer. The cause of the different process results at the different test wafer positions is the dilution of the SiH₄, which in the inner tube 5 increases from the bottom upward, mainly on account of the way in which the H₂ is supplied, and to a slight extent also because of the additional H₂ which is formed from the chemical reaction of the SiH₄ (to form silicon and hydrogen on the hot surfaces of the wafers and the inner tube). The result is that, in the single-step process according to the invention, a dilution ratio of the SiH₄ can be used to set a semiconductor grain size.

To assess a temperature dependency, a suitable temperature profile is established; specifically, a temperature of 590 degrees Celsius is established in the upper region, a temperature of 570 degrees Celsius is established in the central region and a temperature of 550 degrees Celsius is established in the lower region. In this case, three test wafers with a 30 nm thick oxide layer are used, one in each temperature zone.

In a first test, a strong H₂ dilution of the SiH₄ is selected, with the H₂ dilution as well as the temperature increasing from the bottom upward for the reasons which have already been mentioned above. The total flow rate of the dilution gas H₂ is 800 sccm, the flow rate of SiH₄ (b) is 40 sccm, and the flow rate of SiH₄ (t) is 0 sccm. The pressure is increased to 53.3 Pascal (400 mTorr) and a deposition time of 30 minutes is selected. On account of the influences of both the dilution and the temperature, the following picture is established: in the upper region of the furnace or boat 6 (590 degrees Celsius), insular layer growth with thicknesses of at least 13 to at most 28 nm is obtained. Therefore, there is no continuous layer, but rather islands with a very uneven lateral extent. In the central region, at the temperature of 570 degrees Celsius and the decreasing H₂ dilution, the grain heights range from at least 28 to at most 33 nm, resulting in a substantially continuous layer being established because of the semiconductor grains coalescing or growing together. Only in the lower region, at a temperature of 550 degrees Celsius, are grain heights of at least 40 to at most 50 nm established, lying close together and having a relatively uniform size. In a second test on the temperature dependency, an N₂ dilution is analyzed, once again using an inclined temperature profile. Unlike when diluting with H₂, in this case the dilution gas is mixed with SiH₄ even before it enters the tube. Consequently, the dilution ratio is virtually constant throughout the entire tube and the temperature is the defining parameter which distinguishes the three test wafer positions. The flow rate of SiH₄ (b) is in this case 40 sccm, the flow rate of SiH₄ (t) is 0 sccm and the flow rate of N₂ is 4000 sccm. The deposition time is once again 30 minutes, with a pressure of 600 mTorr being established. In the upper region, at a temperature of 590 degrees Celsius, grain heights of at least 31 to at most 46 nm are established, with substantial coalescence of the semiconductor grains being recorded, but without a continuous layer being formed. In the central region, at a temperature of 570 degrees Celsius, grain heights of at least 15 to at most 24 nm are established, with coalescence of the semiconductor grains being recorded, but already with more voids than at 590 degrees Celsius. In the lower region of the furnace, at a temperature of 550 degrees Celsius, minimum grain heights of approx. 5 nm to maximum grain heights of approx. 10 nm are produced, very small, individual beads of a uniform shape but different size being formed. Under these process conditions (pressure, gas flow rates, deposition time), the result is that the appropriate deposition temperature is 560 degrees Celsius.

In a further series of tests, using N₂ as the dilution gas, the deposition time, the dilution ratio and the type of wafer surfaces are varied. For a 30 nm thick oxide surface, a flow rate of 40 sccm of SiH₄ (b) and of 0 sccm of SiH₄ (t) and of 400 sccm of N₂, with a deposition time of 15 minutes, a pressure of 26.6 Pascal (200 mTorr) and a temperature of 560 degrees Celsius, result in grain heights of at least 9 to at most 17 nm. The semiconductor grains in this case formed small individual beads of uniform shape and different sizes. To obtain larger grains, in one variant the time was increased, in another variant the dilution was reduced. In both variants, the grain growth was investigated on test wafers with 30 nm silicon oxide surfaces and 4.5 nm silicon nitride surfaces.

If the deposition time is increased from 15 to 30 minutes, with otherwise identical process parameters, the result, for the 30 nm oxide surface, is grain heights of at least 15 to at most 25 nm, the semiconductor grains being partially agglomerated and having uneven lateral sizes. By contrast, a substantially continuous layer with individual holes is formed on the 4.5 nm thick nitride surface. The thickness of this continuous layer is between 19 and 26 nm.

In the second variant aimed at increasing the grain sizes, the deposition time was left at 15 minutes, but the dilution was reduced, by lowering the N₂ flow rate from 400 sccm to 200 sccm. The other process parameters remained unchanged. The resultant grain heights on the oxide surface are in this case at least 20 to at most 31 nm, the semiconductor grains being partially agglomerated, the lateral size being more uniform and the intermediate spaces being smaller than with the first variant. On the nitride surface, the semiconductor grains are very similar to those on the oxide surface, but thicker and with smaller intermediate spaces. The grain heights are at least 24 to at most 33 nm. The differences in the growth on oxide and nitride with this variant involving weaker dilution are therefore smaller.

In a further series of tests, the influence of various preliminary cleaning processes on the process according to the invention for the production of microroughness is determined. In this case, a silicon substrate which has undergone various preliminary cleaning treatments is used instead of the oxide or nitride. The process parameters for producing the microroughness on the silicon surface are set at a SiH₄ (b) flow rate of 40 sccm and an N₂ flow rate of 200 sccm. The deposition time is 15 minutes at a temperature of 560 degrees Celsius and a pressure of 26.6 Pascal (200 mTorr). A so-called piranha preliminary cleaning operation results in grain heights of at least 17 to at most 28 nm. Preliminarily piranha cleaning in combination with preliminary RCA cleaning results in grain heights of at least 14 to at most 24 nm. Furthermore, the use of piranha cleaning in combination with a HF dip cleaning results in grain heights of at least 23 to at most 30 nm, with large irregular semiconductor grains being recorded.

Contrary to usual expectations, therefore, it is surprisingly possible for microroughness to be formed on different wafer surfaces in a single process step, at process pressures which are similar to those customarily used in LPCVD processes.

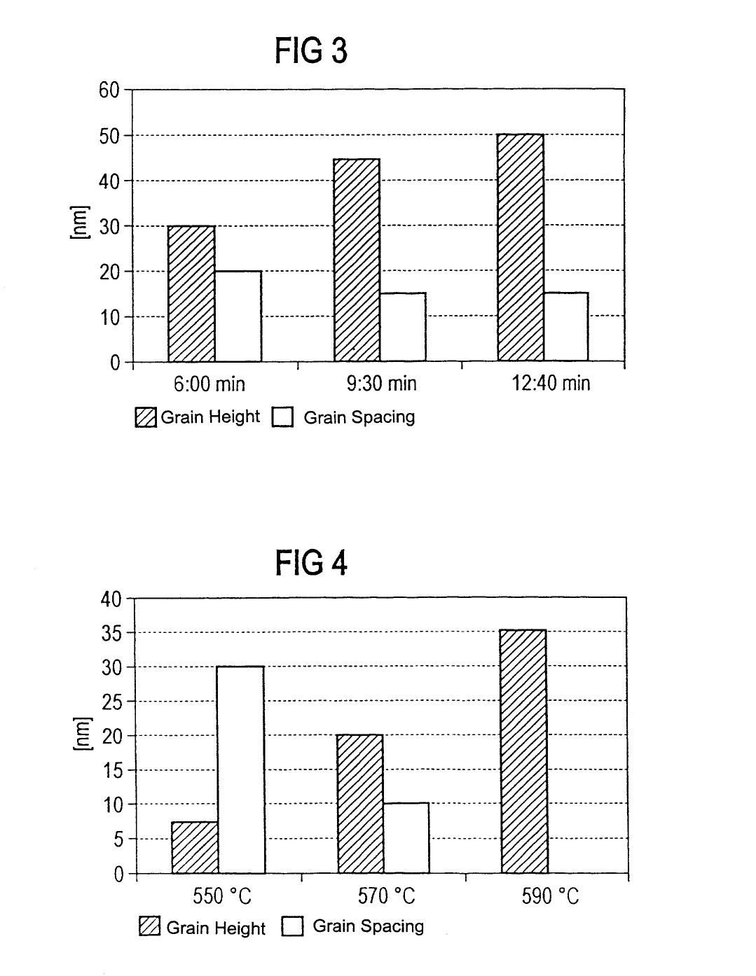

FIGS. 3 to 7 show charts which provide a summary illustration of the test results which have been described above. It should be pointed out at this point that the term grain height is understood as meaning the vertical distance of the highest point of a semiconductor grain 1 from the planar wafer surface beneath it; with a continuous layer, this is equal to the layer thickness. The following diagrams in each case only show a mean value for the grain height or layer thickness. In this context, the term grain spacing is understood as meaning the clear spacing between the lateral surfaces of two adjacent grains. A spacing equal to zero means that the grains have agglomerated. Since the diagrams described below in each case give a mean spacing, the indication “zero” does not necessarily mean a smooth, continuous layer, but also describes substantial coalescence of the grains.

FIG. 3 shows a chart illustrating the grain height and grain spacing as a function of a deposition time, with a constant H₂ dilution of 1:0.2. Under these process conditions, deposition times of from 6 minutes to 12 minutes 40 seconds still give adequate test results. Depending on the selection of the further parameters, which determine the deposition rate or seeding rate, in particular therefore the dilution and the temperature, it is possible to set the deposition time in such a manner that, on the one hand, sufficiently large semiconductor grains are formed and, on the other hand, a continuous layer is not formed. Consequently, deposition times of 5 minutes to 60 minutes can lead to useable results.

FIG. 4 shows a chart illustrating the grain height and grain spacing as a function of a particular process temperature.

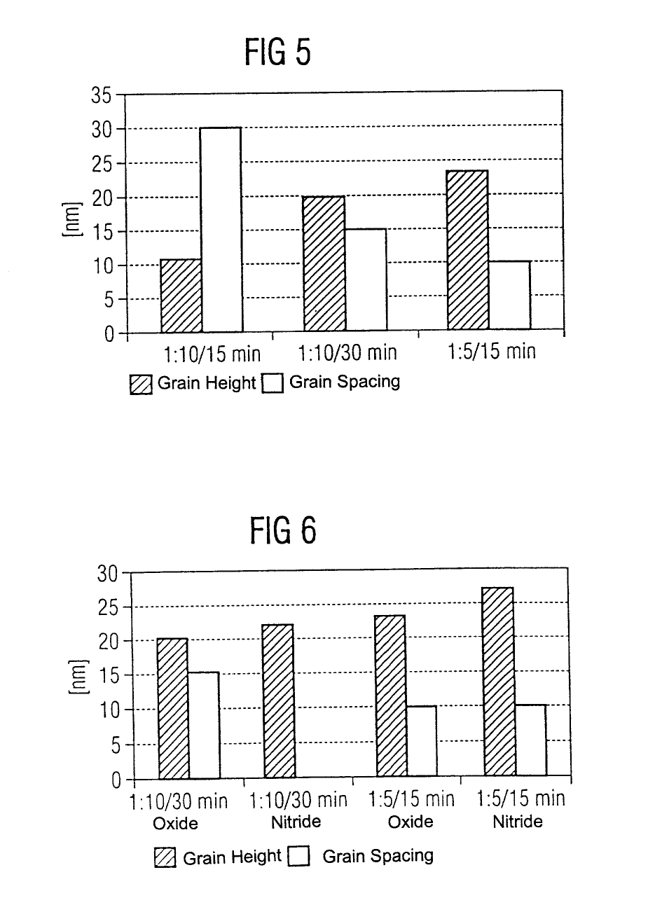

An inclined temperature profile of this nature can be set through the use of separately controllable heating zones in the upper, central and lower regions of the boat 6 in the furnace 4. As shown in FIG. 4, substantial coalescence of the semiconductor grains is recorded at a temperature of 590 degrees Celsius, i.e. the mean grain spacing is zero. With a sufficiently strong dilution and a deposition time which is not too long, FIG. 5 shows that the formation of isolated grains can also occur at higher temperatures. Therefore, depending on the further process parameters, the result is a temperature range from 500 degrees Celsius to 600 degrees Celsius, a temperature of 560 degrees Celsius preferably being used.

FIG. 5 shows the grain heights and grain spacings with different silane dilutions and deposition times. The test series using the parameters “1:10/15 minutes” leads to grain sizes which are still too small and spacings which are too wide for an effective increase in the surface area. Both can be improved both by a longer deposition time and by a weaker dilution of the silane as shown in FIG. 5. However, it should be pointed out that these two variants behave differently when used on different wafer surfaces, as described below with reference to FIG. 6.

FIG. 6 shows a chart illustrating the grain height and the grain spacing as a function of the type of wafer or type of surface. Oxide and nitride surfaces are compared using two different process variants which lead to approximately identical grain heights. (Two combinations of dilution and deposition time, namely 1:10/30 minutes and 1:5/15 minutes, mean grain heights between 20 and 27 nm.)

However, significant differences occur in terms of the grain spacing. With the stronger dilution but longer deposition time, a substantially continuous layer grows on nitride, i.e. the grain spacing is equal to zero. By contrast, with a lower dilution and a shorter deposition time, it is observed that isolated grains with a similar grain spacing grow on both types of surfaces, and consequently the deposition is less strongly dependent on the type of surface. On the other hand, the different seeding behavior of different surfaces can also be utilized in a targeted manner when employing a stronger dilution.

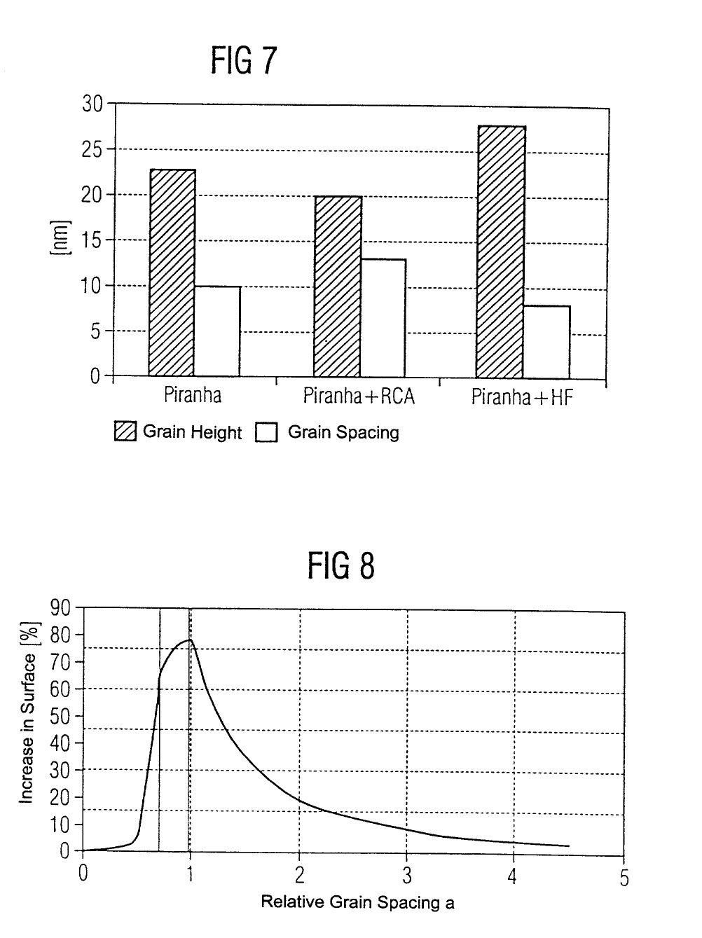

FIG. 7 shows a chart illustrating the way in which grain height and grain spacing are dependent on a type of preliminary cleaning carried out. In accordance with FIG. 7, piranha cleaning, piranha+RCA or piranha+HF cleaning were applied to a silicon substrate. There is no need for a detailed description of these conventional wet-chemical cleaning methods at this point, since they are extensively known to the person skilled in the art. In accordance with FIG. 7, the grain height and the grain spacing, when using silicon substrate wafers, are accordingly also dependent on the preliminary cleaning carried out. Piranha and RCA cleaning leave behind a thin, wet-chemical oxide (hydrophilic), while HF dip cleaning leads to a hydrogen-terminated silicon surface without oxide (hydrophobic). With the hydrophobic preliminary cleaning, relatively large, irregularly shaped grains are formed.

To summarize, in addition to the various temperature, pressure, time and dilution ranges, there is also a particularly advantageous combination of process parameters for an optimum increase in the surface area:

| | |
|---|---|
| Dilution: | 1:5 |
| Temperature: | 560 degrees Celsius |
| Deposition time: | 15 minutes |
| Process pressure: | 26.6 Pascal (200 mTorr). |

For simple assessment of the test results described above, a simple theoretical model for estimating the increase in surface area produced by silicon grains is described below.

According to this simple theoretical model, it is assumed that hemispherical grains of uniform diameter are provided on a planar surface in a regular square grid. The diameter of the hemispheres is D, the distance between the center points of the hemispheres is A (this distance should not be confused with the grain spacing described in FIGS. 3 to 7). For this theoretical model, the relative grain spacing (or more accurately, the relative distance between the center points of the grains) is defined as a=A/D, since the relative or percentage increase in surface area is dependent only on this variable.

FIG. 8 shows a graph which illustrates this theoretical model. For a relative grain spacing of a=2, the distance between the center points is twice as great as the grain diameter, and consequently the clear distance between two adjacent grains or hemisphere surfaces is equal to the diameter. With a relative grain spacing of a=1, adjacent grains touch one another, resulting in a maximum increase in surface area. With a relative grain spacing of a=1/\sqrt{2}, diagonally opposite grains, i.e. the grains of in each case the next but one neighbors, in the square grid touch one another. The relative grain spacing a=0 describes a smooth, continuous layer of thickness D/2, so that there is no increase in surface area.

When using this highly simplified theoretical model, the deviations which occur in reality have to be taken into account and their influence estimated. Firstly, the grains are not all at the same distance from one another and are not disposed regularly. This means that some individual grains already agglomerate even before the densest packing has been reached. The maximum increase in surface area of the theoretical model (in which all the adjacent grains just touch one another) therefore cannot be achieved at least with hemispherical grains. Furthermore, the actual semiconductor grains are not hemispherical, but rather in some cases are almost spherical. This in turn leads to a slightly greater increase in surface area than in the theoretical model described above. Furthermore, not all the semiconductor grains are of identical size, although a good approximation is achieved using the theoretical model described above if a mean grain size is specified.

In reality, therefore, the increase in surface area will always be slightly below the curve illustrated in FIG. 8. In particular, the maximum level of the curve lies at a relative grain spacing a of slightly greater than 1. However, this theoretical model is of considerable assistance in estimating the possible increase in surface area through the use of the single-step process according to the invention and the most favorable grain spacings.

The invention has been described above on the basis of a LPCVD furnace. However, it is not restricted to this configuration and can in fact be implemented in all other currently available or future furnaces. Furthermore, the present invention has been described on the basis of trench capacitors for DRAM memory circuits. However, the invention is not restricted to this application and rather encompasses all further processes for producing enlarged surface areas, for example embedded DRAM and non-volatile semiconductor memory circuits.

We claim:

1. A process for producing a microroughness on a surface, the process which comprises:
forming, in a single process step, semiconductor grains directly from a process gas such that the semiconductor grains are distributed on a surface for producing a microroughness on the surface.

2. The process according to claim 1, which comprises:
providing the semiconductor grains as grains selected from the group consisting of Si grains and Ge grains; and
providing the process gas as a gas selected from the group consisting of SiH₄ or GeH₄.

3. The process according to claim 1, wherein the step of forming the semiconductor grains is performed in a temperature range extending from 500 degrees Celsius to 600 degrees Celsius.

4. The process according to claim 1, wherein the step of forming the semiconductor grains is performed at a pressure between 13 Pascal and 80 Pascal.

5. The process according to claim 1, wherein the step of forming the semiconductor grains is performed in a period lasting between 5 minutes and 60 minutes.

6. The process according to claim 1, which comprises using a material selected from the group consisting of an oxide, a nitride and a Si-substrate for providing the surface.

7. The process according to claim 6, which comprises precleaning the Si substrate.

8. The process according to claim 7, wherein the precleaning step includes at least one cleaning step selected from the group consisting of a piranha cleaning, an RCA cleaning and a HF-dip cleaning.

9. The process according to claim 1, which comprises providing the process gas with an H₂ dilution in a range from 1:20 to 1:0.2.

10. The process according to claim 1, which comprises providing the process gas with an N₂ dilution in a range from 1:100 to 1:5.

11. A process for producing a microroughness on a surface, the process which consists of: forming semiconductor grains distributed on a surface for producing a microroughness on the surface by forming the semiconductor grains directly from a process gas.
